(19) United States
(12) Patent Application Publication
(10) Pub. No.: US 2012/0098737 A1
(43) Pub. Date: Apr. 26, 2012

(54) Organic light-emitting diode display device

(76) Inventors: Tae-Gon Kim, Yongin-City (KR); Yun-Sik Ham, Yongin-City (KR); Sung-Joo Hwang, Yongin-City (KR); Chi-Wook An, Yongin-City (KR)

(21) Appl. No.: 13/137,961

(22) Filed: Sep. 22, 2011

(30) Foreign Application Priority Data
Oct. 22, 2010 (KR) 10-2010-0103674

(51) Int. Cl. G09G 3/30

(52) U.S. Cl. 345/76

(57) ABSTRACT

An organic light-emitting diode (OLED) includes a substrate partitioned into a plurality of pixel regions, and a first electrode in each of the pixel regions on the substrate. The first electrode is partitioned into a first emission region and a second emission region. The OLED includes a first intermediate layer in the first emission region of the first electrode, a second intermediate layer in the second emission region of the first electrode, a second electrode interposed between the first electrode and the second intermediate layer, and a third electrode disposed on the first and second intermediate layers. Light generated by the first intermediate layer is transmitted through the first and third electrodes, and light generated by the second intermediate layer is transmitted through the third electrode.

### BACKGROUND

1. Field

Embodiments relate to an organic light-emitting diode (OLED) display device.

2. Description of the Related Art

Flat panel display (FPD) devices may be classified into emissive devices and non-emissive devices. The emissive devices may include flat cathode ray tubes (flat CRTs), plasma display panels (PDPs), and light-emitting diode (LED) display devices. The non-emissive devices may include liquid crystal display (LCD) devices. Among these, the LED display devices may have wide viewing angles, high contrasts, and/or high response speeds. The LED display devices may include an organic LED (OLED) display device.

### SUMMARY

Embodiments are directed to light-emitting diode (LED) display devices, and organic light-emitting diode (OLED) display devices. An organic light-emitting diode (OLED) display device having a resonance structure may reduce, e.g., a failure rate, and improve throughput.

Embodiments may be realized by providing an OLED display device including a substrate partitioned into a plurality of pixel regions, a first electrode disposed in each of the pixel regions on the substrate and partitioned into a first emission region and a second emission region, a first intermediate layer disposed in the first emission region of the first electrode, a second intermediate layer disposed in the second emission region of the first electrode, a second electrode interposed between the first electrode and the second intermediate layer, and a third electrode disposed on the first and second intermediate layers. Light generated by the first intermediate layer is transmitted through the first and third electrodes, and light generated by the second intermediate layer is transmitted through the third electrode.

The substrate may transmit the light generated by the first intermediate layer.

The first electrode may transmit the light generated by the first intermediate layer.

The first electrode may be a transparent electrode.

The first electrode may include at least one of indium tin oxide (ITO), indium zinc oxide (IZO), zinc oxide (ZnO), and indium oxide (In₂O₃).

The first electrode may include crystallized ITO.

The second electrode may reflect the light generated by the second intermediate layer.

The second electrode may include a plurality of metal layers stacked on the first electrode.

The second electrode may include a first metal layer and a second metal layer stacked on the first electrode.

The first metal layer may include a metal that reflects light generated by the second intermediate layer, and the second metal layer may include a metal that transmits light generated by the second intermediate layer.

The first metal layer may include at least one of silver (Ag), magnesium (Mg), aluminum (Al), platinum (Pt), palladium (Pd), gold (Au), nickel (Ni), neodymium (Nd), iridium (Ir), and chromium (Cr), and the second metal layer may include at least one of ITO, IZO, ZnO, and In₂O₃.

The second electrode may further include a third metal layer interposed between the first electrode and the first metal layer.

The third metal layer may include at least one of ITO, IZO, ZnO, and In₂O₃.

The first electrode may have a greater thickness than the second metal layer and the third metal layer.

The light generated by the first intermediate layer may have the same optical distance as the light generated by the second intermediate layer to produce the same resonance effects.

The first intermediate layer may have the same thickness as the second intermediate layer.

The third electrode may be a transparent electrode or a transmission electrode.

The transmission electrode may include magnesium-silver (MgAg).

The third electrode may have a thickness of about 100 Å to about 200 Å.

The OLED display device may further include an encapsulation member disposed on the substrate and configured to encapsulate the pixel regions.

The encapsulation member may transmit the light generated by the first and second intermediate layers.

The OLED display device may further include a pixel defining layer disposed on the substrate and having an opening exposing the first electrode, a pixel circuit unit interposed between the substrate and the first electrode and electrically connected to the first electrode, and an insulating layer interposed between the pixel circuit unit and the first electrode.

The pixel circuit unit may be a thin-film transistor (TFT).

The pixel circuit unit may be disposed on the substrate to correspond to the pixel defining layer.

The first and second intermediate layers may include the same material.

### BRIEF DESCRIPTION OF THE DRAWINGS

Features will become more apparent to those of ordinary skill in the art by describing in detail exemplary embodiments with reference to the attached drawings in which:

FIG. 1 illustrates a cross-sectional view of an organic light-emitting diode (OLED) display device according to an exemplary embodiment; and

FIG. 2 illustrates a cross-sectional view of a pixel region of an organic emission unit shown in FIG. 1.

### DETAILED DESCRIPTION

Korean Patent Application No. 10-2010-0103674, filed on Oct., 22, 2010, in the Korean Intellectual Property Office, and entitled: “Organic Light-Emitting Diode Display Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

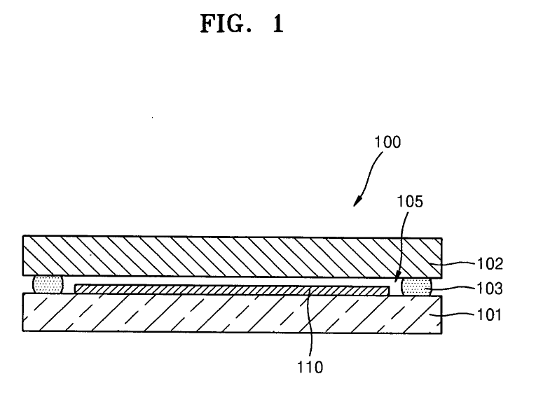

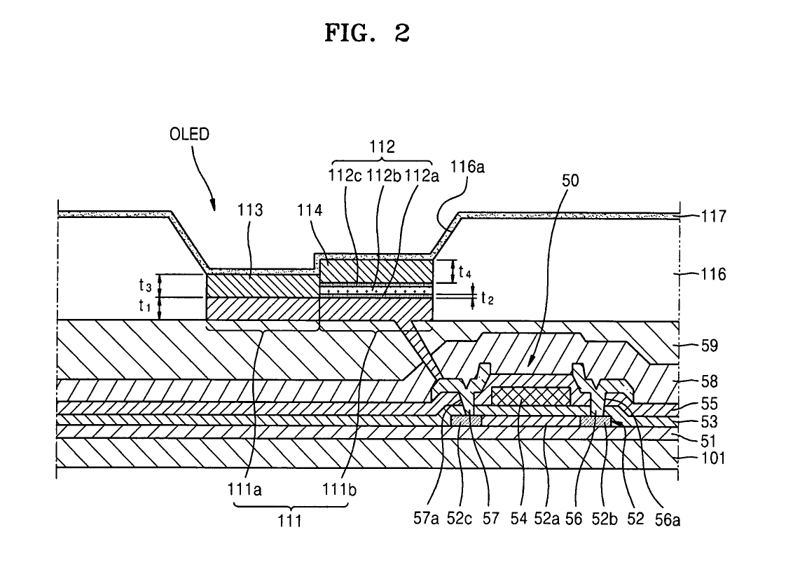

FIG. 1 illustrates a cross-sectional view of an organic light-emitting diode (OLED) display device 100 according to an exemplary embodiment. FIG. 2 illustrates a cross-sectional view of a pixel region of an organic emission unit 110 shown in FIG. 1.

Referring to FIG. 1, the OLED display device 100 according to an exemplary embodiment may include a substrate 101, an encapsulation member 102, a bonding member 103, and the organic emission unit 110.

The substrate 101 may be a transparent substrate, e.g., may be formed of a transparent glass material containing SiO₂ as a main component. The substrate 101 is not limited thereto and may be formed of other materials, e.g., a transparent plastic material. The transparent plastic material may be at least one or one insulating organic material selected from the group consisting of polyethersulphone (PES), polyacrylate (PAR), polyetherimide (PEI), polyethylene naphthalate (PEN), polyethyelene terephthalate (PET), polyphenylene sulfide (PPS), polyallylate, polyimide (PI), polycarbonate (PC), cellulose tri-acetate (TAC), and cellulose acetate propionate (CAP). The substrate 101 may be partitioned into a plurality of pixel regions. An OLED may be disposed on each of the pixel regions of the substrate 101.

The encapsulation member 102 may be formed of, e.g., a transparent glass material or a plastic material like the substrate 101. Edges of the encapsulation member 102 and the substrate 101 may be combined by the bonding member 103 to, e.g., hermetically seal a space 105 between the substrate 101 and the encapsulation member 102. A moisture absorbent material or filler may be disposed in the space 105. The encapsulation member 102 is not limited thereto. For example, the encapsulation member 102 may be a thin film formed on the organic emission unit 110. The encapsulation member 102, e.g., as a thin film, may have a structure obtained by stacking, e.g., alternately stacking, an inorganic layer formed of, e.g., a silicon oxide or a silicon nitride, and an organic layer formed of, e.g., an epoxy or a polyimide.

Both the substrate 101 and the encapsulation member 102 may be formed of a transparent material so that an image can be embodied due to light generated by the organic emission unit 110. The substrate 101 and the encapsulation member 102 may minimize, reduce, and/or prevent the diffusion of air and moisture into the organic emission unit 110.

The bonding member 103 may function to, e.g., bond the substrate 101 with the encapsulation member 102. The bonding member 103 may be formed of, e.g., an organic sealant, such as an epoxy. Also, the bonding member may include or may be a frit. Frit may refer to, e.g., a glass powder, a gel glass obtained by adding an organic material to glass powder, and a solid glass cured by irradiating laser beams to the glass powder. The bonding of the substrate 101 with the encapsulation member 102 using the frit may include coating an edge of the encapsulation member 102 with the frit, disposing the encapsulation member 102 on the substrate 101, and sealing the substrate 101 and the encapsulation member 102 by curing the frit by irradiating laser beams to the frit while moving a laser irradiation system.

The organic emission unit 110 may include a plurality of OLEDs and a pixel circuit unit 50. Referring to FIG. 2, a buffer layer 51 may be formed on the substrate 101, and the pixel circuit unit 50 and the OLEDs may be formed on the buffer layer 51. The pixel circuit unit 50 may be one of various thin-film transistors (TFTs), such as a top-gate TFT and a bottom-gate TFT. The pixel circuit unit 50 may be disposed on the substrate 101 to correspond to a pixel defining layer 116. This will be described later.

An active layer 52 having a predetermined pattern may be disposed on the buffer layer 51 of the substrate 101. A gate insulating layer 53 may be disposed on the active layer 52. A gate electrode 54 may be formed on a predetermined region of the gate insulating layer 53. The gate electrode 54 may be connected to a gate line (not shown) via which, e.g., TFT on/off signals may be applied. An interlayer insulating layer 55 may be formed on the gate electrode 54. Source and drain electrodes 56 and 57 may be formed to contact respective source and drain regions 52b and 52c of the active layer 52 through respective contact holes 56a and 57a. An insulating layer may be formed on the source and drain electrodes 56 and 57. The insulating layer may include a passivation layer 58 formed of, e.g., SiO₂ and/or SiNₓ, and a planarization layer 59 formed of, e.g., an organic material, such as acryl, PI, and/or benzocyclobutene (BCB).

A first electrode 111 may be formed on the planarization layer 59. The planarization layer 59 may correspond to a pixel region P of the substrate 101. The first electrode 111 may be patterned to correspond to each of the plurality of pixel regions P. The first electrode 111 may be an anode or a cathode. A third electrode 117 may be disposed opposite the first electrode 111. The third electrode 117 may overlap the first electrode 111. The first electrode 111 may be under the third electrode 117, and other components of the OLED may be between the first electrode 111 and the third electrode 117. When the first electrode 111 is an anode, the third electrode 117 may be a cathode, and when the first electrode 111 is a cathode, the third electrode 117 may be an anode.

The first electrode 111 may be a transparent electrode. For example, the first electrode 111 may be capable of transmitting light generated by a first intermediate layer 113. Since the substrate 101 may also transmits light, the light generated by the first intermediate layer 113 may be transmitted through the first electrode 111 and the substrate 101 to embody an image in the direction of the substrate 101. The first electrode 111, which may be the anode, may be formed of a material having a large work function, such as ITO, IZO, ZnO, and/or In₂O₃.

For example, when the first electrode 111 includes ITO, the first electrode 111 may be formed of polycrystalline ITO. The polycrystalline ITO may be denser and more durable than amorphous ITO. Without intending to be bound by this theory, the first electrode 111 formed of polycrystalline ITO may minimize, reduce, and/or prevent surface damage during a subsequent process, e.g., an etching process for forming a second electrode 112. Since the surface damage to the first electrode 111 formed of polycrystalline ITO may be minimized, bonding characteristics between the first electrode 111 and the first intermediate layer 113 disposed on the first electrode 111 may be improved. The polycrystalline ITO may be formed by, e.g., annealing amorphous ITO at a temperature of about 200° C. to about 400° C.

The first electrode 111 may be partitioned into a first emission region 111a and a second emission region 111b. First and second emission regions 111a and 111b may be adjacent to each other. The first intermediate layer 113 may be formed in the first emission region 111a. The second electrode 112 may be formed in the second emission region 111b. The second electrode 112 may be, e.g., a reflective electrode. When the second electrode 112 and a second intermediate layer 114 are stacked in the second emission region 111b of the first electrode 111, light generated by the second intermediate layer 114 may be reflected by the second electrode 112 and emitted toward the encapsulation member 102. Therefore, a top-emission-type OLED may be embodied in the second emission region 111b. In the first emission region 111a, the light generated by the first intermediate layer 113 may be transmitted through the first electrode 111 to embody an image toward the substrate 101. The light generated by the first intermediate layer 113 may also be transmitted through the third electrode 117 to embody an image toward the encapsulation member 102. Thus, both top and bottom-emission-type OLEDs may be embodied in the first emission region 111a.

The second electrode 112 may include a plurality of metal layers. For example, as shown in FIG. 2, the second electrode 112 may include three metal layers. According to an exemplary embodiment, the second electrode 112 may include a third metal layer 112a, a first metal layer 112b, and a second metal layer 112c stacked on the first electrode 111. According to another exemplary embodiment, the second electrode 112 may include a first metal layer 112b and a second metal layer 112c stacked on the first electrode 111.

The second metal layer 112c and the third metal layer 112a may form a transmission electrode or a transparent electrode, and the first metal layer 112b may be formed of a metal capable of reflecting the light generated by the second intermediate layer 114. The second metal layer 112c and the third metal layer 112a may be formed of, e.g., ITO, IZO, ZnO, and/or In₂O₃. The first metal layer 112b may be formed of, e.g., silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), a mixture thereof, or an alloy thereof.

The first electrode 111 may be formed to have a thickness t1 that is greater than a thickness t2 of the third metal layer 112a. For example, the thickness t1 of the first electrode 111 may be at least twice the thickness t2 of the third metal layer 112a. Without intending to be bound by this theory, the first electrode 111 may be formed to a greater thickness than the third metal layer 112a so that damage to the first electrode 111 may be reduced during, e.g., formation of the second electrode 112 using an etching process. That is, the second electrode 112 may be formed by stacking a metal on the first electrode 111 and patterning the metal using an etching process. Since the third metal layer 112a of the second electrode 112 and the first electrode 111 may be formed of the same material, e.g., ITO, by forming the first electrode 111 to a greater thickness, the damage to the first electrode 111 may be minimized, reduced, and/or prevented during the etching process for forming the second electrode 112.

The pixel defining layer 116 may have an opening 116 that, e.g., exposes the first and second electrodes 111 and 112. The pixel defining layer 116 may be formed on the planarization layer 59. The pixel defining layer 116 may be formed of, e.g., an organic material. The pixel circuit unit 50 may be formed on a portion of the substrate 101 corresponding to the pixel defining layer 116, e.g., the pixel circuit unit 50 may be under the pixel defining layer 116. Since the light generated by the first intermediate layer 113 may be transmitted through the first electrode 111 and emitted toward the substrate 101, the pixel circuit unit 50 may be disposed to correspond to the pixel defining layer 116 instead of the pixel region of the substrate 101. Without intending to be bound by this theory, this arrangement may improve extraction efficiency of the light generated by the first intermediate layer 113 and transmitted through the first electrode 111. The first and second intermediate layers 113 and 114 may be formed on the first and second electrodes 111 and 112 exposed by the opening 116a of the pixel defining layer 116. For example, the first intermediate layer 113 may be disposed on the first electrode 111 in the first emission region 111a. The second intermediate layer 114 may be disposed on the both the first electrode 111 and the second electrode 112 in the second emission region 111b.

Each of the OLEDs may emit red (R), green (G), and blue (B) light according to the flow of current, and display predetermined image information. According to an exemplary embodiment, each of the OLEDs may include the first electrode 111 connected to a drain electrode 57 of the TFT, and may be configured to receive positive power from the drain electrode 57 of the TFT. The third electrode 117 may be configured to cover the entire pixel and may be configured to supply negative power. The first and second intermediate layers 113 and 114 may be interposed between the first and third electrodes 111 and 117, and may be configured to emit light. The first and second intermediate layers 113 and 114 may be disposed between the first electrode 111 and the third electrode 117. Voltages having different polarities may be applied to the first and second intermediate layers 113 and 114 so that the first and second intermediate layers 113 and 114 may emit light.

In this case, each of the first and second intermediate layers 113 and 114 may be formed of, e.g., a monomer organic layer and/or a polymer organic layer. When each of or one of the first and second intermediate layers 113 and 114 are formed of the monomer organic layer, the monomer organic layer may be formed by stacking at least one of a hole injection layer (HIL), a hole transport layer (HTL), an emission layer (EML), an electron transport layer (ETL), and an electron injection layer (EIL). Also, the monomer organic layer may be formed of one of various organic materials, such as copper phthalocyanine (CuPc), N,N′-Di(naphthalene-1-yl)-N,N′-diphenyl-benzidine (NPB), or tris-8-hydroxyquinoline aluminum (Alq3). The monomer organic layer may be obtained using, e.g., a vacuum evaporation process.

When each or one of the first and second intermediate layers 113 and 114 are formed of the polymer organic layer, the polymer organic layer may at least include an HTL and an EML. In this case, the HTL of the polymer organic layer may be formed of, e.g., PEDOT. The EML of the polymer organic layer may be formed of, e.g., a polymer organic material, such as a poly-phenylenevinylene(PPV)-based material or a polyfluorene-based material. The polymer organic layer may be formed using, e.g., a screen printing process or an inkjet printing process. The first and second intermediate layers 113 and 114 may be formed using, e.g., an inkjet process. The first and second intermediate layers 113 and 114 may be formed using, e.g., a spin coating process.

The first and second intermediate layers 113 and 114 are not limited to the above description and various embodiments may be applied.

The first intermediate layer 113 may be formed in the first emission region 111a of the first electrode 111. The second intermediate layer 114 may be formed on the second electrode 112 formed in the second emission region 111b of the first electrode 111. As described above, since the first and third electrodes 111 and 117 may be transparent electrodes and the second electrode 112 may be a reflective electrode, light generated by the first intermediate layer 113 may be transmitted through the first and third electrodes 111 and 117 to embody an image in the substrate 101 and the encapsulation member 102, and light generated by the second intermediate layer 114 may be transmitted through the third electrode 117 and reflected by the second electrode 112 to embody an image in the encapsulation member 102. That is, according to an exemplary embodiment, top and bottom-emission operations may be enabled in a single sub-pixel. The top and bottom-emission operations may be controlled by a single transistor.

The light generated by the first intermediate layer 113 may be reflected and emitted between the first electrode 111 and the third electrode 117, while the light generated by the second intermediate layer 114 may be reflected and emitted between the second electrode 112 and the third electrode 117. Without intending to be bound by this theory, light generated by the first intermediate layer 113 may have the same resonance effect as light generated by the second intermediate layer 114. The light may produce resonance effects according to, e.g., a distance t3 between the first and third electrodes 111 and 117, and a distance t4 between the second electrode 112 and the third electrode 117.

According to an exemplary embodiment, both the first and second intermediate layers 113 and 114 perform top-emission operations in a single pixel. Light generated by the second intermediate layers 113 and 114 may have the same resonance effect to embody the same color. Accordingly, the distance t3, e.g., an optical distance, between the first and third electrodes 111 and 117 may be the distance t4, e.g., an optical distance, between the second and third electrodes 112 and 117. The first intermediate layer 113 may be formed to a thickness t3 equal to a thickness t4 of the second intermediate layer 114 to provide the same optical distance in the first and second emission regions 111a and 111b. The first and second intermediate layers 113 and 114 may be formed using the same process so that the thickness t3 of the first intermediate layer 113 can be the same as the thickness t4 of the second intermediate layer 114. Without intending to be bound by this theory, a failure rate caused by forming the first and second intermediate layers 113 and 114 to different thicknesses may be reduced, and the first and second intermediate layers 113 and 114 may be formed using the same process to the same thickness, thereby improving throughput.

The third electrode 117 may be formed on the first and second intermediate layers 113 and 114. The third electrode 117 may be a transmission electrode or a transparent electrode. The third electrode 117 may be formed of a conductive metal having a small work function, which may be one material selected from the group consisting of Mg, Ca, Al, Ag, and an alloy thereof. For example, the third electrode 117 may be formed of MgAg. In this case, the third electrode 117 may be formed to a thickness of about 100 Å to 200 Å to maximize light extraction efficiency.

According to the exemplary embodiments, as described above, an OLED display device can have a resonance structure, enable both-sided emission operations, improve throughput, and reduce a failure rate.

By way of summation and review, the LED display devices may be classified, e.g., into inorganic LED (ILED) display devices and organic LED (OLED) display devices, according to materials forming an emission layer (EML) in the display device. An OLED display device may be an emissive display configured to emit light by electrically exciting a fluorescent organic compound. The OLED display device has become strongly relied upon, e.g., as an advanced display capable of solving problems of an LCD. For example, the OLED display device may be driven at a low voltage, easily made thin, and have wide viewing angles and fast response speeds.

The OLED display device may include an EML formed of an organic material between an anode and a cathode. In the OLED display device, an anode voltage and a cathode voltage may be applied to the anode and cathode, respectively, so that holes can be moved from the anode to the EML through a hole transport layer (HTL), and electrons move from the cathode through an electron transport layer (ETL) to the EML. Thus, the electrons and the holes may recombine in the EML, thereby generating excitons.

While the excitons transition from an excited state to a ground state, fluorescent molecules of the EML may emit light, thereby creating an image. A full-color OLED display device may include pixels configured to emit red (R), green (G), and blue (B) light to embody full color. In the OLED display device, a pixel defining layer may be formed at both ends of the anode. Also, a predetermined opening may be formed in the pixel defining layer, and the EML and the cathode may be sequentially formed on an exposed top surface of the anode

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light-emitting diode (OLED) device, comprising:
a substrate partitioned into a plurality of pixel regions;
a first electrode in each of the pixel regions on the substrate, the first electrode being partitioned into a first emission region and a second emission region;
a first intermediate layer in the first emission region of the first electrode;
a second intermediate layer in the second emission region of the first electrode;
a second electrode interposed between the first electrode and the second intermediate layer; and
a third electrode disposed on the first and second intermediate layers, wherein:
light generated by the first intermediate layer is transmitted through the first and third electrodes; and
light generated by the second intermediate layer is transmitted through the third electrode.

2. The device as claimed in claim 1, wherein the substrate transmits the light generated by the first intermediate layer.

3. The device as claimed in claim 1, wherein the first electrode transmits the light generated by the first intermediate layer.

4. The device as claimed in claim 3, wherein the first electrode is a transparent electrode.

5. The device as claimed in claim 4, wherein the first electrode includes at least one of indium tin oxide (ITO), indium zinc oxide (IZO), zinc oxide (ZnO), and indium oxide (In₂O₃).

6. The device as claimed in claim 4, wherein the first electrode includes crystallized ITO.

7. The device as claimed in claim 1, wherein the second electrode reflects the light generated by the second intermediate layer.

8. The device as claimed in claim 1, wherein the second electrode includes a plurality of metal layers stacked on the first electrode.

9. The device as claimed in claim 8, wherein the second electrode includes a first metal layer and a second metal layer, the first and second metal layers being stacked on the first electrode.

10. The device as claimed in claim 9, wherein the first metal layer includes a metal that reflects light generated by the second intermediate layer, and the second metal layer includes a metal that transmits light generated by the second intermediate layer.

11. The device as claimed in claim 10, wherein the first metal layer includes at least one of silver (Ag), magnesium (Mg), aluminum (Al), platinum (Pt), palladium (Pd), gold (Au), nickel (Ni), neodymium (Nd), iridium (Ir), and chromium (Cr), and the second metal layer includes at least one of ITO, IZO, ZnO, and In₂O₃.

12. The device as claimed in claim 8, wherein the second electrode further includes a third metal layer interposed between the first electrode and the first metal layer.

13. The device as claimed in claim 12, wherein the third metal layer includes at least one of ITO, IZO, ZnO, and In₂O₃.

14. The device as claimed in claim 12, wherein the first electrode has a greater thickness than the second metal layer and the third metal layer.

15. The device as claimed in claim 1, wherein the light generated by the first intermediate layer has a same optical distance as a light generated by the second intermediate layer to produce the same resonance effect.

16. The device as claimed in claim 15, wherein the first intermediate layer has a same thickness as the second intermediate layer.

17. The device as claimed in claim 1, wherein the third electrode is a transparent electrode or a transmission electrode.

18. The device as claimed in claim 17, wherein the transmission electrode includes magnesium-silver (MgAg).

19. The device as claimed in claim 18, wherein the third electrode has a thickness of about 100 Å to about 200 Å.

20. The device as claimed in claim 1, further comprising an encapsulation member disposed on the substrate and configured to encapsulate the pixel regions.

21. The device as claimed in claim 20, wherein the encapsulation member transmits the light generated by the first and second intermediate layers.

22. The device as claimed in claim 1, further comprising:
a pixel defining layer on the substrate, the pixel defining layer having an opening exposing the first electrode;
a pixel circuit unit interposed between the substrate and the first electrode, the pixel circuit unit being electrically connected to the first electrode; and
an insulating layer interposed between the pixel circuit unit and the first electrode.

23. The device as claimed in claim 22, wherein the pixel circuit unit is a thin-film transistor (TFT).

24. The device as claimed in claim 22, wherein the pixel circuit unit is on the substrate and corresponds to the pixel defining layer.

25. The device as claimed in claim 1, wherein the first and second intermediate layers include a same material.
